(19) United States
(12) Patent Application Publication
(10) Pub. No.: US 2025/0180998 A1
(43) Pub. Date: Jun. 5, 2025

(54) DRIVE DEVICE, OPTICAL SYSTEM AND LITHOGRAPHY APPARATUS

(71) Applicant: Carl Zeiss SMT GmbH, Oberkochen (DE)

(72) Inventor: Oliver HERBST, Aalen (DE)

(21) Appl. No.: 19/046,226

(22) Filed: Feb. 5, 2025

Related U.S. Application Data
(63) Continuation of application No. PCT/EP2023/071848, filed on Aug. 7, 2023.

(30) Foreign Application Priority Data
Aug. 8, 2022 (DE) 10 2022 208 231.1

(51) Int. Cl. G03F 7/00; G02B 26/08

(52) U.S. Cl. CPC G03F 7/70266; G02B 26/0833; G03F 7/70316

(57) ABSTRACT

A drive device for driving at least one actuator for actuating an optical element of an optical system, wherein the drive device comprises an end stage configured to boost an input voltage using a quiescent current of the end stage to a drive voltage for the actuator. The drive device also comprises a supply device configured to adjust the quiescent current for the end stage depending on a specific dynamics request for the end stage.

### CROSS-REFERENCE TO RELATED APPLICATIONS

The present application is a continuation of, and claims benefit under 35 USC 120 to, international application No. PCT/EP2023/071848, filed Aug. 7, 2023, which claims benefit under 35 USC 119 of German Application No. 10 2022 208 231.1, filed Aug. 8, 2022. The entire disclosure of each of these applications is incorporated by reference herein.

### FIELD

The present disclosure relates to a drive device for driving at least one actuator of an optical system, to an optical system having such a drive device, and to a lithography apparatus having such an optical system.

### BACKGROUND

Microlithography apparatuses which have actuatable optical elements, such as microlens arrays or micromirror arrays, are known. Microlithography is used to produce microstructured devices, such as integrated circuits. The microlithography process is carried out with a lithography apparatus, which comprises an illumination system and a projection system.

Driven by the desire for ever smaller structures in the production of integrated circuits, EUV lithography apparatuses which use light with a wavelength in the range of 0.1 nm to 30 nm, such as 13.5 nm, are currently being developed. Since most materials absorb light of this wavelength, reflective optical units, i.e., mirrors, are usually used in such EUV lithography apparatuses instead of refractive optical units, i.e., lens elements, as has been done up to this point.

The image of a mask (reticle) illuminated using the illumination system is projected by the projection system onto a substrate, for example a silicon wafer, which substrate is coated with a light-sensitive layer (photoresist) and is arranged in the image plane of the projection system, in order to transfer the mask structure to the light-sensitive coating of the substrate. Actuable optical elements can be used to improve the imaging of the mask on the substrate. For example, wavefront errors that result in magnified and/or blurred image representations during exposure can be compensated for.

For example, a MEMS actuator (MEMS; microelectromechanical system) or a PMN actuator (PMN; lead magnesium niobate) can be used as an actuator. A PMN actuator can enable path positioning in the sub-micrometer range or sub-nanometer range. Due to the application of a DC voltage, the actuator, whose actuator elements are stacked on top of one another, is subject to a force which causes a specific longitudinal extension. The position set by the DC voltage (DC; direct current) can be negatively influenced by external electromechanical crosstalk at the resonance points of the actuator driven by the DC voltage resulting from the principles involved. MEMS mirrors and actuators suitable for actuating them are described, for example, in DE 10 2016 213 025 A1.

For relatively precise actuator control, for example for a multiplicity of MEMS mirrors, a class A amplifier can be desirable as an output stage because of the low signal distortion. However, class A amplifiers can involve a relatively high quiescent current, which can lead to high waste heat. Especially if there are many MEMS mirrors, this might not tolerable in some cases. By contrast, a reduction in the quiescent current of the class A amplifier can reduce the bandwidth and thus the reaction time of the actuator. An issue is that the quiescent current of the class A amplifier defines the bandwidth of the class A amplifier. In general, the higher the quiescent current is, the faster a capacitive actuator, for example, can be recharged. However, as stated, this can result in a significantly higher power loss.

### SUMMARY

The present disclosure seeks to improve the driving of an actuator of an optical system.

According to a first aspect, a drive device for driving at least one actuator is proposed. The drive device comprises:
an output stage, which is configured to amplify an input voltage using a quiescent current of the output stage into a drive voltage for the actuator; and
a provision device, which is configured to set the quiescent current for the output stage in dependence on a specific dynamic requirement for the output stage.

In the present drive device, the quiescent current of the output stage is set in dependence on the dynamic requirement for the output stage. The dynamic requirement specifies the required dynamics of the output stage at a specific point in time. If, for example, the capacitive actuator to be driven is to be recharged quickly, the dynamic requirement is large and the quiescent current is quickly increased.

The following example can illustrate this. For example, the dynamic requirement is based on a change in the input voltage of the output stage, such as on a derivative of the input voltage du/dt. In this example, a high du/dt corresponds to a high dynamic requirement.

As a result, the quiescent current, for example, is increased proportionally at a high du/dt. In other words, du/dt is directly proportional to the change in the quiescent current. For a negative du/dt, the change and thus the effect in the other direction becomes effective. Here, the quiescent current is reduced, which can reduce the power consumption.

In other words, a high quiescent current is set only for a high dynamic requirement in order to correspondingly be able to provide a short reaction time of the actuator. At all other times, only a small quiescent current is used to minimize the corresponding waste heat.

As a result, the temporarily increased quiescent current temporarily provides a high recharge speed. Otherwise, a low quiescent current is used, especially at a constant actuator position, to reduce the waste heat.

The present drive device causes less power loss, thus less waste heat and thus the possibility of simplifying the cooling concept of the optical system.

The present drive device can also be referred to as a drive device with dynamic quiescent current or as an amplifier stage for driving an actuator with integrated adaptation of the dynamics.

The actuator can be a MEMS actuator, a capacitive actuator, for example a PMN actuator (PMN; lead magnesium niobate), or a PZT actuator (PZT; lead zirconate titanate), or a LiNbO3 actuator (lithium niobate). The actuator can be configured to actuate an optical element of the optical system. Examples of such an optical element include lens elements, mirrors, and adaptive mirrors.

The optical system can be a projection optical unit of the lithography apparatus or projection exposure apparatus. However, the optical system can also be an illumination system. The projection exposure apparatus can be an EUV lithography apparatus. EUV stands for “extreme ultraviolet” and refers to a wavelength of the working light of between 0.1 nm and 30 nm. The projection exposure apparatus can also be a DUV lithography apparatus. DUV stands for “deep ultraviolet” and refers to a wavelength of the working light of between 30 nm and 250 nm.

According to one embodiment, the output stage comprises a class A amplifier. The class A amplifier exhibits only little signal distortion and therefore provides precise actuator control.

According to one embodiment, the output stage comprises a class AB amplifier. The class AB amplifier is a suitable alternative to the proposed class A amplifier.

According to one embodiment, the output stage comprises an input node for receiving the input voltage of the output stage, an output node for providing the drive voltage to the actuator, and a transistor coupled between the input node and the output node for amplifying the input voltage into the drive voltage.

According to one embodiment, the provision device comprises a provision unit, which is configured to set the quiescent current for the output stage in dependence on the specific dynamic requirement for the output stage and to feed it into the output node of the output stage. The provision unit can be implemented in software, as a discrete circuit or as an ASIC and converts the specific or specified dynamic requirement for the output stage directly into a corresponding quiescent current for the output stage. A discrete circuit is in particular a circuit constructed on a circuit board comprising standard components, for example comprising resistors, transistors, capacitors, operational amplifiers and the like.

The quiescent current is in particular the current that flows through the output stage, even if it is not dynamically active. The quiescent current is used to set the operating point at the output node. In the present case, this operating point is briefly shifted by the provision device in dependence on the dynamic requirement. The quiescent current can also be referred to as the bias current.

According to one embodiment, the provision device comprises:
a control unit, which is configured to provide a current indicative of the specific dynamic requirement, and
a current mirror, which is configured to mirror the current indicative of the specific dynamic requirement to provide the quiescent current and to feed the quiescent current provided into the output node of the output stage.

The control unit can be implemented in software, as a discrete circuit or as an ASIC and converts the specific dynamic requirement into a current that is indicative of the dynamic requirement. This current, which is indicative of the dynamic requirement, is then mirrored by the current mirror into the quiescent current in order to then feed the quiescent current provided into the output node of the output stage.

According to one embodiment, the control unit is configured to provide the current indicative of the specific dynamic requirement based on a change in the input voltage of the output stage, for example based on a derivative of the input stage of the output stage.

According to one embodiment, the provision device comprises:
a controlling unit, which is configured to provide a voltage indicative of the specific dynamic requirement,
a voltage-dependent current source, which is configured to convert the voltage, which is indicative of the specific dynamic requirement, into a current proportional thereto, and
a current mirror, which is configured to mirror the converted proportional current to provide the quiescent current and to feed the quiescent current provided into the output node of the output stage.

The controlling unit can be implemented in software, as a discrete circuit or as an ASIC and provides a voltage indicative of the specific dynamic requirement. This voltage, which is indicative of the dynamic requirement, is then converted by the voltage-dependent current source into a current correspondingly proportional thereto. This converted current is in turn indicative of the specific dynamic requirement and is provided to the current mirror, which mirrors the converted proportional current and feeds it as a quiescent current into the output stage. The current mirror can also be referred to as the current mirror circuit.

According to one embodiment, the controlling unit is configured to provide the voltage indicative of the specific dynamic requirement based on a change in the input voltage of the output stage, for example based on a derivative of the input voltage of the output stage.

According to one embodiment, the provision device comprises:
a differential amplifier circuit, which is configured to receive the input voltage of the output stage on the input side and, in dependence thereon, to provide a voltage indicative of the specific dynamic requirement on the output side,
a voltage-dependent current source, which is configured to convert the voltage, which is indicative of the specific dynamic requirement, into a current proportional thereto, and
a current mirror, which is configured to mirror the converted proportional current to provide the quiescent current and to feed the quiescent current provided into the output node of the output stage.

This embodiment of the provision device can be implemented entirely in hardware. In this embodiment, the dynamic requirement is derived from the input voltage of the output stage. For example, the first derivative of the input voltage is equated to the dynamic requirement. The dynamic requirement is then implemented therewith as du/dt, wherein u denotes the input voltage and t denotes the time.

According to one embodiment, the differential amplifier circuit is configured to provide the voltage indicative of the specific dynamic requirement based on a change in the input voltage of the output stage, for example based on a derivative of the input voltage of the output stage.

According to one embodiment, the differential amplifier circuit comprises:
an input node for receiving the input voltage of the output stage,
an output node for providing the voltage indicative of the specific dynamic requirement,
an operational amplifier coupled between the input node and the output node,
a series circuit of a capacitor and a resistor coupled between the input node and the inverting input of the operational amplifier for providing a dynamically varying component of the indicative voltage in dependence on the input voltage received at the input node,
a voltage divider coupled to the non-inverting input of the operational amplifier for providing a DC component for the indicative voltage, and
a resistor circuit with at least one resistor coupled between the inverting input of the operational amplifier and the output node.

According to one embodiment, the drive device comprises a plurality N of output stages for the respective driving of an actuator via a respective drive voltage. In this case, the current mirror is configured to mirror the current which is indicative of the specific dynamic requirement N-fold to provide a respective quiescent current and to feed the quiescent current respectively provided into the respective output node of the respective output stage.

This embodiment can be desirable, for example, when a multiplicity N of optical elements are to be actuated by a corresponding multiplicity N of actuators. In this embodiment, only a single current mirror is then required for driving the N actuators, which current mirror mirrors the current indicative of the specified dynamic requirement, valid for all N actuators, N-fold in order to provide a respective quiescent current for the respective output stage. In addition to the use of a smaller number of component parts, to be specific only one current mirror, is that the N output stages can be driven identically.

The respective unit, for example the control unit, can be implemented in hardware and/or also software. In a hardware implementation, the unit may be designed as a device or as part of a device, for example as a computer or as a microprocessor or as part of the control device. In a software implementation, the unit may be designed as a computer program product, as a function, as a routine, as part of a program code, or as an executable object.

According to a second aspect, an optical system with a number of actuable optical elements is proposed, wherein each of the actuable optical elements of the number is assigned an actuator, wherein each actuator is assigned a drive device for driving the actuator according to the first aspect or according to one of the embodiments of the first aspect.

The optical system can comprise a micromirror array and/or a microlens array having a multiplicity of independently actuable optical elements.

In embodiments, groups of actuators can be defined, wherein all actuators of one group are assigned the same drive device.

According to one embodiment, the optical system is formed as an illumination optical unit or as a projection optical unit of a lithography apparatus.

According to one embodiment, the optical system has a vacuum housing, in which the actuable optical elements, the assigned actuators, and the drive device are arranged.

According to a third aspect, a lithography apparatus is proposed, which comprises an optical system according to the second aspect or according to one of the embodiments of the second aspect.

The lithography apparatus is, for example, an EUV lithography apparatus, whose working light lies in a wavelength range of 0.1 nm to 30 nm, or a DUV lithography apparatus, whose working light lies in a wavelength range of 30 nm to 250 nm.

According to a fourth aspect, a method for operating a drive device for driving at least one actuator is proposed, which an output stage, which to amplifies an input voltage into a drive voltage for the actuator using a quiescent current of the output stage. The quiescent current for the output stage is set in dependence on a specific dynamic requirement for the output stage.

The method has the corresponding features, which have been explained in relation to the drive device according to the first aspect. The embodiments described for the drive device apply correspondingly to the proposed method.

“A/one” should not necessarily be understood here to be limited to exactly one element. Rather, a plurality of elements, such as two, three or more, may also be provided. Any other counter word used here should also not be understood to be limited to exactly the specified number of elements. Rather, numerical deviations upward and downward are possible, unless otherwise indicated.

Further possible implementations of the disclosure also comprise combinations not explicitly mentioned of features or embodiments which were described previously or are described in the following text with regard to the exemplary embodiments. A person skilled in the art will also add individual aspects as improvements or additions to the respective basic form of the disclosure.

Further embodiments and aspects of the disclosure are the subject of the dependent claims and of the exemplary embodiments of the disclosure described below. The disclosure is furthermore elucidated in detail on the basis of embodiments with reference to the appended figures.

### BRIEF DESCRIPTION OF THE DRAWINGS

FIG. 1 shows a schematic meridional section of a projection exposure apparatus for EUV projection lithography;

FIG. 2 shows a schematic illustration of an embodiment of an optical system;

FIG. 3 shows a schematic block diagram of a first embodiment of a drive device for driving an actuator for actuating an optical element of an optical system;

FIG. 4 shows a schematic block diagram of a second embodiment of a drive device for driving an actuator for actuating an optical element of an optical system;

FIG. 5 shows a schematic block diagram of a third embodiment of a drive device for driving an actuator for actuating an optical element of an optical system; and

FIG. 6 shows a schematic block diagram of a fourth embodiment of a drive device for driving an actuator for actuating an optical element of an optical system.

In the figures, identical or functionally identical elements have been provided with the same reference signs, unless otherwise indicated. It should also be noted that the illustrations in the figures are not necessarily to scale.

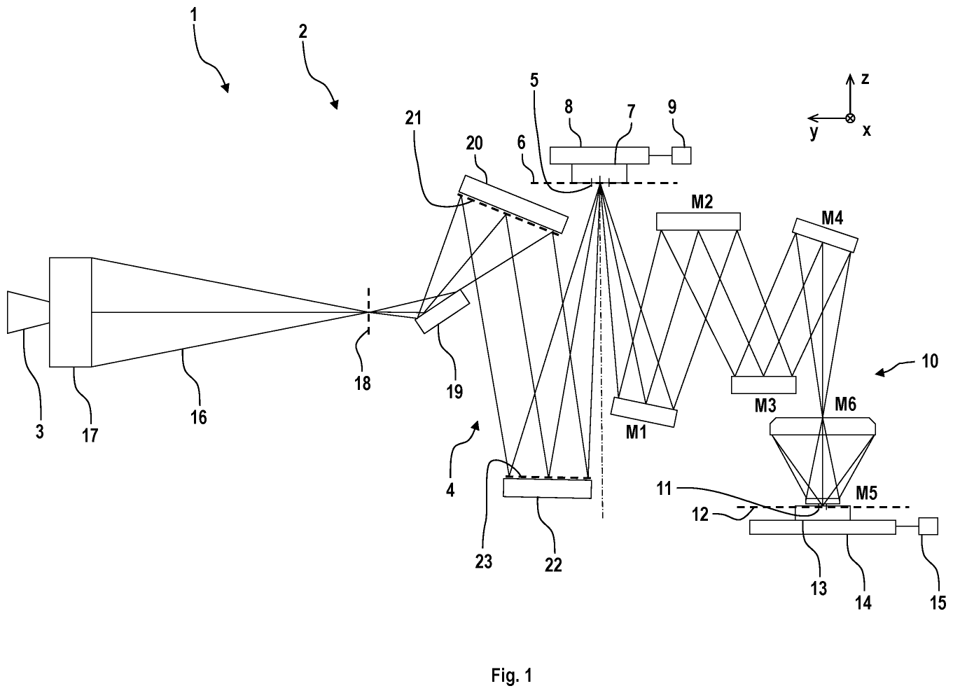

FIG. 1 shows an embodiment of a projection exposure apparatus 1 (lithography apparatus), in particular an EUV lithography apparatus. An embodiment of an illumination system 2 of the projection exposure apparatus 1 has, in addition to a light or radiation source 3, an illumination optical unit 4 for illuminating an object field 5 in an object plane 6. In an alternative embodiment, the light source 3 may also be provided as a module separate from the rest of the illumination system 2. In this case, the illumination system 2 does not include the light source 3.

A reticle 7 arranged in the object field 5 is exposed. The reticle 7 is held by a reticle holder 8. The reticle holder 8 is displaceable by way of a reticle displacement drive 9, such as in a scanning direction.

FIG. 1 shows, by way of illustration, a Cartesian coordinate system with an x-direction x, a y-direction y, and a z-direction z. The x-direction x runs perpendicularly into the plane of the drawing. The y-direction y runs horizontally, and the z-direction z runs vertically. The scanning direction runs in the y-direction y in FIG. 1. The z-direction z runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. Alternatively, an angle that differs from 0° between the object plane 6 and the image plane 12 is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, such as in the y-direction y. The displacement firstly of the reticle 7 by way of the reticle displacement drive 9 and secondly of the wafer 13 by way of the wafer displacement drive 15 may be implemented so as to be mutually synchronized.

The light source 3 is an EUV radiation source. The light source 3 emits EUV radiation 16, which is also referred to below as used radiation, illumination radiation or illumination light. For example, the used radiation 16 has a wavelength in the range between 5 nm and 30 nm. The light source 3 can be a plasma source, for example an LPP (short for: laser produced plasma) source or a DPP (short for: gas-discharge produced plasma) source. It can also be a synchrotron-based radiation source. The light source 3 can be an FEL (short for: free-electron laser).

The illumination radiation 16 emanating from the light source 3 is focused by a collector 17. The collector 17 may be a collector with one or more ellipsoidal and/or hyperboloidal reflection surfaces. The at least one reflection surface of the collector 17 can be impinged upon by the illumination radiation 16 with grazing incidence (abbreviated as: GI), which is to say with angles of incidence greater than 45°, or with normal incidence (abbreviated as: NI), which is to say with angles of incidence less than 45°. The collector 17 may be structured and/or coated, both to optimize its reflectivity for the used radiation and to suppress extraneous light.

The illumination radiation 16 propagates through an intermediate focus in an intermediate focal plane 18 downstream of the collector 17. The intermediate focal plane 18 may represent a separation between a radiation source module, comprising the light source 3 and the collector 17, and the illumination optical unit 4.

The illumination optical unit 4 comprises a deflection mirror 19 and, arranged downstream thereof in the beam path, a first facet mirror 20. The deflection mirror 19 may be a plane deflection mirror or, alternatively, a mirror with a beam-influencing effect going beyond the pure deflection effect. As an alternative or in addition, the deflection mirror 19 may be in the form of a spectral filter that separates a used light wavelength of the illumination radiation 16 from extraneous light of a different wavelength. If the first facet mirror 20 is arranged in a plane of the illumination optical unit 4 which is optically conjugate to the object plane 6 as a field plane, then this facet mirror is also referred to as a field facet mirror. The first facet mirror 20 comprises a multiplicity of individual first facets 21, which may also be referred to as field facets. Only some of these first facets 21 are shown in FIG. 1 by way of example.

The first facets 21 may be designed as macroscopic facets, such as rectangular facets or as facets with an arc-shaped edge contour or an edge contour of part of a circle. The first facets 21 may be in the form of plane facets or, alternatively, of convexly or concavely curved facets.

As is known for example from DE 10 2008 009 600 A1, the first facets 21 themselves may each also be composed of a multiplicity of individual mirrors, such as a multiplicity of micromirrors. The first facet mirror 20 can be in the form of a microelectromechanical system (MEMS system). For details, reference is made to DE 10 2008 009 600 A1.

The illumination radiation 16 propagates horizontally, i.e. in the y-direction y, between the collector 17 and the deflection mirror 19.

In the beam path of the illumination optical unit 4, a second facet mirror 22 is disposed downstream of the first facet mirror 20. If the second facet mirror 22 is arranged in a pupil plane of the illumination optical unit 4, it is also referred to as a pupil facet mirror. The second facet mirror 22 may also be spaced apart from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 can likewise be macroscopic facets, which can, for example, have a round, rectangular or else hexagonal boundary, or alternatively be facets composed of micromirrors. In this regard, reference is likewise made to DE 10 2008 009 600 A1.

The second facets 23 may have plane or alternatively convexly or concavely curved reflection surfaces.

The illumination optical unit 4 thus forms a double-faceted system. This fundamental principle is also referred to as a fly's eye condenser (or integrator).

It may be desirable to arrange the second facet mirror 22 not exactly in a plane that is optically conjugate to a pupil plane of the projection optical unit 10. For example, the second facet mirror 22 may be arranged so as to be tilted in relation to a pupil plane of the projection optical unit 10, as described for example in DE 10 2017 220 586 A1.

With the aid of the second facet mirror 22, the individual first facets 21 are imaged into the object field 5. The second facet mirror 22 is the last beam-shaping mirror or else actually the last mirror for the illumination radiation 16 in the beam path upstream of the object field 5.

In a further embodiment (not illustrated) of the illumination optical unit 4, a transfer optical unit contributing for example to the imaging of the first facets 21 into the object field 5 may be arranged in the beam path between the second facet mirror 22 and the object field 5. The transfer optical unit may have exactly one mirror, alternatively however even two or more mirrors, which are arranged one behind another in the beam path of the illumination optical unit 4. The transfer optical unit might comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20, and the second facet mirror 22.

In a further embodiment of the illumination optical unit 4, the deflection mirror 19 can also be omitted, so that downstream of the collector 17 the illumination optical unit 4 can then have exactly two mirrors, specifically the first facet mirror 20 and the second facet mirror 22.

The imaging of the first facets 21 into the object plane 6 via the second facets 23, or using the second facets 23, and a transfer optical unit is generally only approximate imaging.

The projection optical unit 10 comprises a plurality of mirrors Mi, which are consecutively numbered in accordance with their arrangement in the beam path of the projection exposure apparatus 1.

In the example shown in FIG. 1, the projection optical unit 10 comprises six mirrors M1 to M6. Alternatives with four, eight, ten, twelve or any other number of mirrors Mi are likewise possible. The projection optical unit 10 is a doubly obscured optical unit. The penultimate mirror M5 and the last mirror M6 each have a passage opening for the illumination radiation 16. The projection optical unit 10 has an image-side numerical aperture that is greater than 0.5 and may also be greater than 0.6 and may be, for example, 0.7 or 0.75.

Reflection surfaces of the mirrors Mi can be in the form of free-form surfaces without an axis of rotational symmetry. As an alternative, the reflection surfaces of the mirrors Mi may be in the form of aspheric surfaces with exactly one axis of rotational symmetry of the reflection surface shape. Just like the mirrors of the illumination optical unit 4, the mirrors Mi may have highly reflective coatings for the illumination radiation 16. These coatings may take the form of multilayer coatings, such as with alternating layers of molybdenum and silicon.

The projection optical unit 10 has a large object-image offset in the y-direction y between a y-coordinate of a center of the object field 5 and a y-coordinate of the center of the image field 11. This object-image offset in the y-direction y may be of approximately the same magnitude as a z-distance between the object plane 6 and the image plane 12.

For example, the projection optical unit 10 may have an anamorphic design. It can have different imaging scales βx, βy in the x- and y-directions x, y. The two imaging scales βx, βy of the projection optical unit 10 can be (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction x, i.e. in a direction perpendicular to the scanning direction.

The projection optical unit 10 leads to a reduction in size of 8:1 in the y-direction y, i.e. in scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 may be the same or may differ, depending on the embodiment of the projection optical unit 10. Examples of projection optical units with different numbers of such intermediate images in the x-direction x and y-direction y are known from US 2018/0074303 A1.

In each case, one of the second facets 23 is assigned to exactly one of the first facets 21 for forming in each case an illumination channel for illuminating the object field 5. This may result in illumination according to the Köhler principle. The far field is decomposed into a multiplicity of object fields 5 with the aid of the first facets 21. The first facets 21 create a plurality of images of the intermediate focus on the second facets 23 respectively assigned to them.

By way of an assigned second facet 23, the first facets 21 are each imaged onto the reticle 7 and overlaid over one another for the purpose of illuminating the object field 5. The illumination of the object field 5 can be as homogeneous as possible. It can have a uniformity error of less than 2%. Field uniformity can be achieved by superposing different illumination channels.

The illumination of the entrance pupil of the projection optical unit 10 may be defined geometrically by an arrangement of the second facets 23. The intensity distribution in the entrance pupil of the projection optical unit 10 may be set by selecting the illumination channels, for example the subset of the second facets 23, which guide light. This intensity distribution is also referred to as illumination setting or illumination pupil filling.

A likewise preferred pupil uniformity in the region of sections of an illumination pupil of the illumination optical unit 4 that are illuminated in a defined manner may be achieved by a redistribution of the illumination channels.

Further aspects and details of the illumination of the object field 5 and in particular of the entrance pupil of the projection optical unit 10 are described below.

The projection optical unit 10 can have a homocentric entrance pupil, for example. The latter may be accessible. It may also be inaccessible.

The entrance pupil of the projection optical unit 10 regularly cannot be exactly illuminated with the second facet mirror 22. In the case of imaging by the projection optical unit 10 which telecentrically images the center of the second facet mirror 22 onto the wafer 13, the aperture rays often do not intersect at a single point. However, it is possible to find an area in which the spacing of the aperture rays that is determined in pairs becomes minimal. This area represents the entrance pupil or an area conjugate thereto in real space. For example, this area exhibits a finite curvature.

It may be the case that the projection optical unit 10 has different positions of the entrance pupil for the tangential beam path and for the sagittal beam path. In this case, an imaging element, such as an optical structural element of the transfer optical unit, should be provided between the second facet mirror 22 and the reticle 7. Using this optical element, the different position of the tangential entrance pupil and of the sagittal entrance pupil may be taken into account.

In the arrangement of the components of the illumination optical unit 4 illustrated in FIG. 1, the second facet mirror 22 is arranged in an area conjugate to the entrance pupil of the projection optical unit 10. The first facet mirror 20 is in a tilted arrangement in relation to the object plane 6. The first facet mirror 20 is arranged with a tilt in relation to an arrangement plane defined by the deflection mirror 19. The first facet mirror 20 is arranged with a tilt in relation to an arrangement plane defined by the second facet mirror 22.

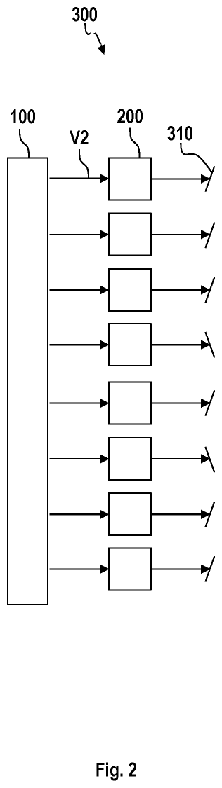

FIG. 2 shows a schematic illustration of an embodiment of an optical system 300 for a lithography apparatus or projection exposure apparatus 1, as shown in FIG. 1, for example. Additionally, the optical system 300 of FIG. 2 may also be used in a DUV lithography apparatus, for example.

The optical system 300 of FIG. 2 has a plurality of actuable optical elements 310. The optical system 300 is designed here as a micromirror array, wherein the optical elements 310 are micromirrors. Each micromirror 310 is actuable via an assigned actuator 200. For example, a respective micromirror 310 can be tilted about two axes and/or displaced in one, two, or three spatial axes via the assigned actuator 200. The reference signs only of the topmost row of these elements are depicted, for reasons of clarity.

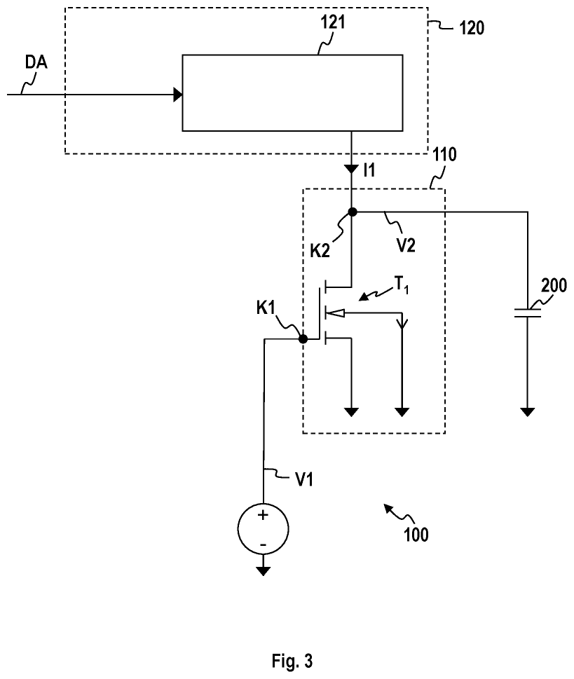

The drive device 100 drives the respective actuator 200, for example, with a drive voltage V2 (see FIGS. 3 to 6). A position of the respective micromirror 310 is thus set. The drive device 100 is described with reference to FIGS. 3 to 6 for example.

FIG. 3 illustrates a schematic block diagram of a first embodiment of a drive device 100 for driving an actuator 200 for actuating an optical element 310 of an optical system 4, 10. The actuator 200 is a capacitive actuator in the embodiments of FIGS. 3 to 6 and is shown in these FIGS. 3 to 6 as a capacitance.

The drive device 100 according to FIG. 3 comprises an output stage 110 and a provision device 120.

The output stage 110 is configured to amplify an input voltage V1 into a drive voltage V2 for the actuator 200 using a quiescent current I1 of the output stage 110. The output stage 110 can be designed as a class A amplifier and comprises a transistor T1. The transistor T1, for example, is a field effect transistor (FET). Alternatively, the transistor T1 may also be designed as a bipolar transistor. As an alternative to the class A amplifier, the output stage 110 can also be designed as a class AB amplifier.

The output stage 110 comprises an input node K1 for receiving the input voltage V1, an output node K2 for providing the drive voltage V2 to the actuator 200, and the transistor T1 coupled between the input node K1 and the output node K2 for amplifying the input voltage V1 into the drive voltage V2.

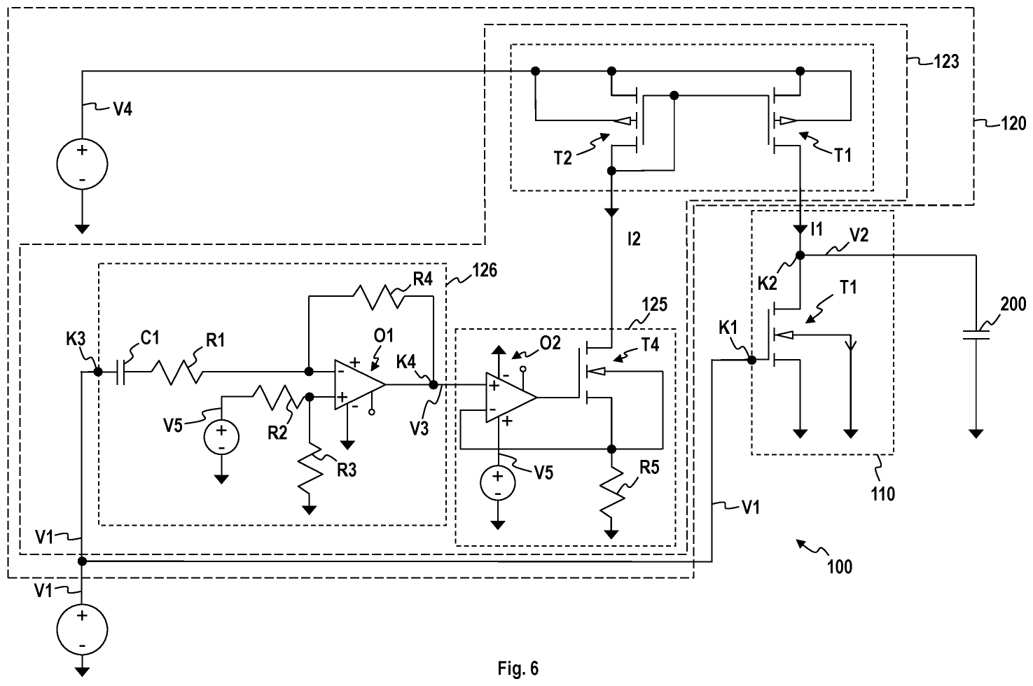

The provision device 120 of FIG. 3 is configured to set the quiescent current I1 for the output stage 110 in dependence on a specific dynamic requirement DA for the output stage 110. The dynamic requirement DA can have been specified or be specified, for example, by a control device (not shown) of the optical system 4, 10. The dynamic requirement DA can also be derived from the input voltage V1 in embodiments (see, for example, FIG. 6 in this regard).

The provision device 120 of FIG. 3, however, comprises a provision unit 121. The provision unit 121 is configured to receive the dynamic requirement DA, for example from the higher-level controlling device of the optical system 4, 10, and to set the quiescent current I1 for the output stage 110 in dependence on the specific dynamic requirement DA and to feed it into the output node K2 of the output stage 110.

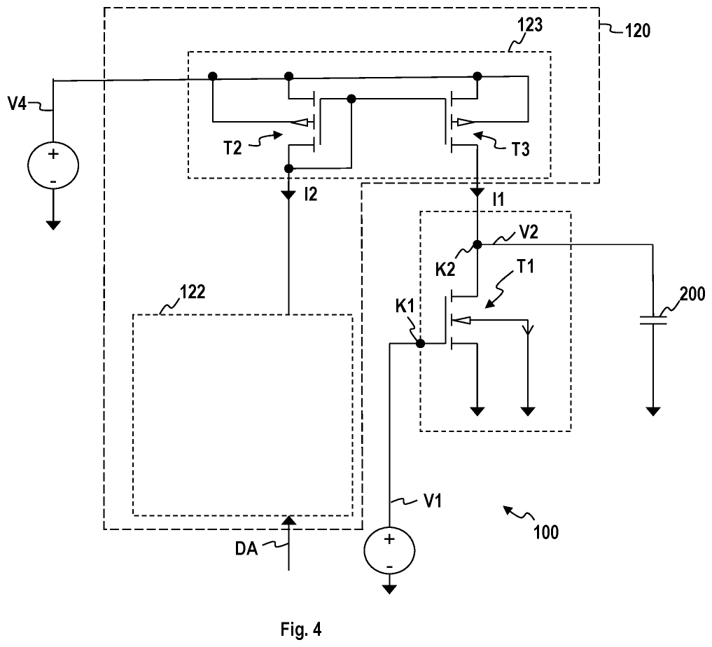

FIG. 4 shows a schematic block diagram of a second embodiment of a drive device 100 for driving an actuator 200 for actuating an optical element 310 of an optical system 4, 10.

The second embodiment according to FIG. 4 differs from the first embodiment according to FIG. 3 in terms of the configuration of the provision device 120.

The provision device 120 according to FIG. 4 comprises a control unit 122 and a current mirror 123. The current mirror 123 can also be referred to as current mirror circuit.

The control unit 122 is configured to provide a current 12 indicative of the specific dynamic requirement DA. The current 12 is indicative of the dynamic requirement DA, which means that the required dynamics at the actuator 200 is represented as a requirement or a piece of information in the current I2.

The current mirror 123 is supplied with a positive supply voltage V4 and is configured to mirror the current 12, which is indicative of the specific dynamic requirement DA, to provide the quiescent current I1 and to feed the quiescent current I1 provided into the output node K2 of the output stage 110.

In this case, the control unit 122 is configured to provide the current 12, which is indicative of the specific dynamic requirement DA, based on a change in the input voltage V1 of the output stage 110. In this case, the control unit 122 can use the provided input voltage V1 of the output stage 110 as a dynamic requirement DA (not shown in FIG. 4).

The control unit 122 can be configured to provide the current 12, which is indicative of the specific dynamic requirement DA, based on a derivative, such as the first derivative, of the input voltage V1 of the output stage 110.

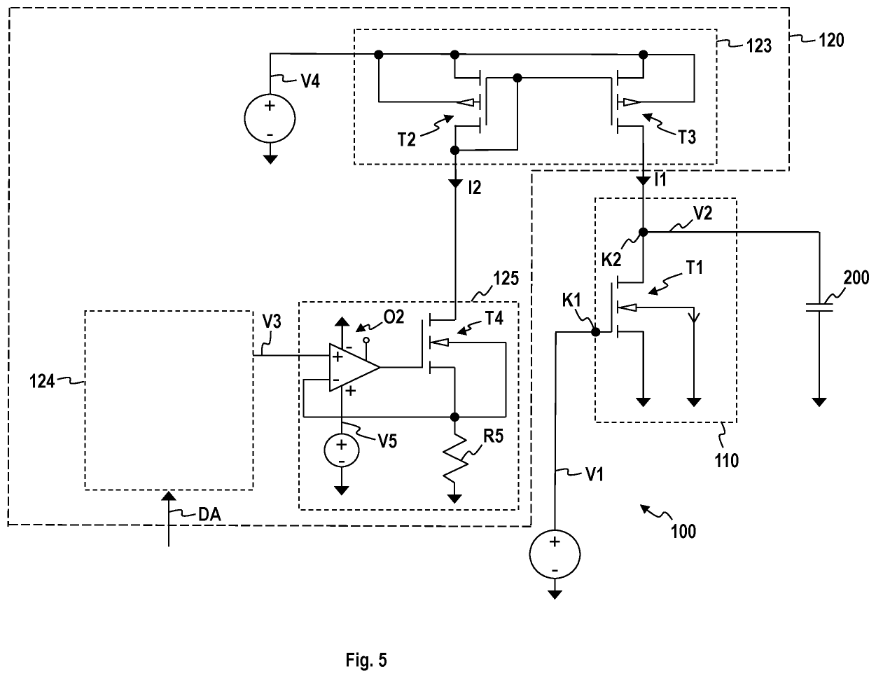

FIG. 5 shows a schematic block diagram of a third embodiment of a drive device 100 for driving an actuator 200 for actuating an optical element 310 of an optical system 4, 10. The third embodiment according to FIG. 5 differs from the embodiments according to FIGS. 3 and 4 in terms of the configuration of the provision device 120.

The provision device 120 according to FIG. 5 comprises a controlling unit 124, a voltage-dependent current source 125, and a current mirror 123. The controlling unit 124 is configured to provide a voltage V3 indicative of the specific dynamic requirement DA.

The voltage-dependent current source 125 is configured to convert the voltage V3, which is indicative of the specific dynamic requirement DA, into a current 12 proportional thereto. Thus, the converted proportional current 12 is also indicative of the specific dynamic requirement DA. The voltage-dependent current source 125 comprises an operational amplifier O2, which is supplied via a supply voltage V5, a transistor T4, for example a field effect transistor, and a resistor R5. The resistor R5 is coupled to the inverting input of the operational amplifier O2 and to the transistor T4, as shown in FIG. 5. The transistor T4 provides the converted proportional current 12 to the current mirror 123 on the output side. The current mirror 123 is formed as explained in FIG. 4. Consequently, the current mirror 123 is configured to mirror the converted proportional current 12 to provide the quiescent current I1 and to feed the provided quiescent current I1 into the output node K2 of the output stage 110.

In this case, the controlling unit 124 is configured in particular to provide the voltage V3, which is indicative of the specific dynamic requirement DA, based on a change in the input voltage V1 of the output stage 110, in particular based on a derivative of the input voltage V1 of the output stage.

FIG. 6 shows a schematic block diagram of a fourth embodiment of a drive device 100 for driving an actuator 200 for activating an optical element 310 of an optical system 4, 10.

The fourth embodiment of the drive device 100 according to FIG. 6 differs from the embodiments according to FIGS. 3, 4 and 5 in terms of the configuration of the provision device 120; otherwise the fourth embodiment according to FIG. 6 corresponds to that according to FIG. 5.

The provision device 120 according to FIG. 6 comprises a differential amplifier circuit 126, a voltage-dependent current source 125 (like FIG. 5), and a current mirror 123 (like FIG. 5).

The differential amplifier circuit 126 is configured to receive the input voltage V1 of the output stage 110 on the input side and, in dependence thereon, to provide a voltage V3 indicative of the specific dynamic requirement DA on the output side. In this case, the differential amplifier circuit 126 is configured in particular to provide the voltage V3, which is indicative of the specific dynamic requirement DA, based on a change in the input voltage V1 of the output stage 110, in particular based on a derivative of the input voltage V1 of the output stage 110.

For this purpose, the differential amplifier circuit 126 comprises an input node K3 for receiving the input voltage V1 of the output stage 110, an output node K4 for providing the voltage V3 indicative of the specific dynamic requirement DA, an operational amplifier O1 coupled between the input node K3 and the output node K4, a series circuit of a capacitor C1 and a resistor R1, coupled between the input node K3 and the inverting input of the operational amplifier O1, for providing a dynamically variable component for the indicative voltage V3 in dependence on the input voltage V1 received at the input node K3, a voltage divider R2, R3 coupled to the non-inverting input of the operational amplifier O1 for providing a DC component for the indicative voltage V3 and a resistor circuit with at least one resistor R4 coupled between the inverting input of the operational amplifier O1 and the output node K4.

Each of the embodiments of the drive device 100 according to FIGS. 4 to 6 can be designed to drive not only one output stage 110, but a plurality N of output stages 110 for respectively driving an actuator 200 with its respective drive voltage V2, with N≥2. For this purpose, the current mirror 123 is configured to mirror the current 12, which is indicative of the specific dynamic requirement DA, N-fold to provide a respective quiescent current I1 and to feed the respectively provided quiescent current I1 into the respective output node K2 of the respective output stage 110.

Although the present disclosure has been described with reference to exemplary embodiments, it is modifiable in various ways.

### List Of Reference Signs

1 Projection exposure apparatus
2 Illumination system
3 Light source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 Illumination radiation
17 Collector
18 Intermediate focus plane
19 Deflection mirror
20 First facet mirror
21 First facet
22 Second facet mirror
23 Second facet
100 Drive device
110 Output stage
120 Provision device
121 Provision unit
122 Control unit
123 Current mirror
124 Controlling unit
125 Voltage-dependent current source
126 Differential amplifier circuit
200 Actuator
300 Optical system
310 Optical element
C1 Capacitor
DA Dynamic requirement
I1 Quiescent current
I2 Indicative current
K1 Input node of the output stage
K2 Output node of the output stage
K3 Input node of the differential amplifier circuit
K4 Output node of the differential amplifier circuit
M1 Mirror
M2 Mirror
M3 Mirror
M4 Mirror
M5 Mirror
M6 Mirror
O1 Operational amplifier
O2 Operational amplifier
R1 Resistor
R2 Resistor
R3 Resistor
R4 Resistor
R5 Resistor
T1 Transistor
T2 Transistor
T3 Transistor
T4 Transistor
V1 Input voltage
V2 Drive voltage
V3 Indicative voltage
V4 Supply voltage
V5 Supply voltage

What is claimed is:

1. An optical system, comprising:
a number of actuable optical elements;
a number of actuators, each actuator assigned to an actuatable optical component;
a drive device configured to drive the actuators, the drive device comprising:
an output stage configured to amplify an input voltage into a drive voltage for an actuator based on a quiescent current of the output stage; and
a provision device configured to set the quiescent current for the output stage depending on a specific dynamic requirement for the output stage,
wherein the specific dynamic requirement is based on a change in the input voltage of the output stage.

2. The optical system of claim 1, wherein the specific dynamic requirement is based on a derivative of the input voltage of the output stage.

3. The optical system of claim 1, wherein the output stage comprises a member selected from the group consisting of a class A amplifier and a class AB amplifier.

4. The optical system of claim 1, wherein the output stage comprises:
an input node configured to receive the input voltage of the output stage;
an output node configured to provide the drive voltage to the actuator; and
a transistor coupled between the input node and the output node, the transistor configured to amplify the input voltage into the drive voltage.

5. The optical system of claim 4, wherein the provision device comprises a provision unit configured to set the quiescent current for the output stage depending on the specific dynamic requirement for the output stage, and the provision device is configured to feed the quiescent current for the output stage into the output node of the output stage.

6. The optical system of claim 4, wherein the provision device comprises:
a control unit configured to provide a current indicative of the specific dynamic requirement; and
a current mirror configured to mirror the current indicative of the specific dynamic requirement to provide the quiescent current and to feed the quiescent current into the output node of the output stage.

7. The optical system of claim 6, wherein the control unit is configured to provide the current indicative of the specific dynamic requirement based on a change in the input voltage of the output stage.

8. The optical system of claim 6, wherein the control unit is configured to provide the current indicative of the specific dynamic requirement based on a derivative of the input voltage of the output stage.

9. The optical system of claim 6, wherein:
the drive device comprises a plurality of output stages;
each output stage is configured to drive a respective actuator via a respective drive voltage;
the current mirror is configured to mirror the current indicative of the specific dynamic requirement N-fold to provide a respective quiescent current and to feed the quiescent current respectively provided into the respective output node of the respective output stage.

10. The optical system of claim 4, wherein the provision device comprises:
a controlling unit configured to provide a voltage indicative of the specific dynamic requirement;
a voltage-dependent current source configured to convert the voltage indicative of the specific dynamic requirement into a current proportional the voltage indicative of the specific dynamic requirement; and
a current mirror configured to mirror the converted proportional current to provide the quiescent current and to feed the quiescent current into the output node of the output stage.

11. The optical system of claim 10, wherein the controlling unit is configured to provide the voltage indicative of the specific dynamic requirement based on a change in the input voltage of the output stage.

12. The optical system of claim 10, wherein the controlling unit is configured to provide the voltage indicative of the specific dynamic requirement a derivative of the input voltage of the output stage.

13. The optical system of claim 4, wherein the provision device comprises:
a differential amplifier circuit configured to: i) receive the input voltage of the output stage on an input side of the differential amplifier circuit; and ii) depending on the input voltage, provide a voltage indicative of the specific dynamic requirement on the output side;
a voltage-dependent current source configured to convert the voltage indicative of the specific dynamic requirement into a current proportional to the specific dynamic requirement; and
a current mirror configured to: i) mirror the current proportional to the specific dynamic requirement to provide the quiescent current; and ii) feed the quiescent current into the output node of the output stage.

14. The optical system of claim 13, wherein the differential amplifier circuit is configured to provide the voltage indicative of the specific dynamic requirement based on a change in the input voltage of the output stage.

15. The optical system of claim 13, wherein the differential amplifier circuit is configured to provide the voltage indicative of the specific dynamic requirement based on a derivative of the input voltage of the output stage.

16. The optical system of claim 13, wherein the differential amplifier circuit comprises:
an input node configured to receive the input voltage of the output stage;
an output node configured to provide the voltage indicative of the specific dynamic requirement;
an operational amplifier coupled between the input node and the output node;
a series circuit of a capacitor and a resistor coupled between the input node and an inverting input of the operational amplifier to provide a dynamically variable component for the indicative voltage depending on the input voltage received at the input node;
a voltage divider coupled to the non-inverting input of the operational amplifier to provide a DC component for the indicative voltage; and
a resistor circuit comprising a resistor coupled between the inverting input of the operational amplifier and the output node.

17. The optical system of claim 1, wherein the optical system is a lithography illumination optical unit.

18. The optical system of claim 17, wherein the actuatable optical elements comprise actuatable mirrors.

19. An apparatus, comprising:
an illumination optical unit configured to illuminate a portion of an object in an object field; and
a projection optical unit configured to image the illuminated portion of the object in the object field into an image field,
wherein the illumination optical unit comprises an optical system according to claim 1, and the apparatus is a lithography projection exposure apparatus.

20. A method of operating a lithography projection exposure apparatus comprising an illumination optical unit and a projection optical unit, the method comprising:
using the illumination optical unit to illuminate a portion of an object in an object field of the projection optical unit; and
using the projection optical unit to image the illuminated portion of the object in the object field into an image field,
wherein the illumination optical unit comprises an optical system according to claim 1.
